(19) United States
(12) Patent Application Publication
(10) Pub. No.: US 2026/0020345 A1
(43) Pub. Date: Jan. 15, 2026

(54) DISPLAY SUBSTRATE AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Xiao WANG, Beijing (CN); Weitao CHEN, Beijing (CN); Yu MA, Beijing (CN); Yan YAN, Beijing (CN)

(73) Assignees: BEIJING BOE DISPLAY TECHNOLOGY CO., LTD., Beijing (CN); BOE TECHNOLOGY GROUP CO., LTD., Beijing (CN)

(21) Appl. No.: 18/994,453

(22) PCT Filed: Apr. 26, 2023
(86) PCT No.: PCT/CN2023/090790

§ 371 Date: Jan. 14, 2025

(51) Int. Cl. H10D 86/40

(52) U.S. Cl. CPC H10D 86/441

(57) ABSTRACT

A display substrate and display device are provided. The display substrate includes a connection structure, a first common electrode, a second common electrode, a first conductive layer, and a second conductive layer, the connection structure includes a first connection portion, a second connection portion, and a conducting portion; the first connection portion is electrically connected to the first common electrode through a first via-hole, and the second connection portion is electrically connected to the second common electrode through a second via-hole; the conducting portion includes a first conducting sub-portion and a second conducting sub-portion; the first connection portion is electrically connected to the second connection portion through the first conducting sub-portion, and the first connection portion is electrically connected to the second connection portion through the second conducting sub-portion; a length-width ratio of the first via-hole is X1, and a length-width ratio of the second via-hole is X2, with X1<1<X2.

### TECHNICAL FIELD

The present disclosure relates to the field of display technologies, in particular to a display substrate and display device.

### BACKGROUND

In related art, high refresh rate products (such as esports display products) can have a refresh rate of over 240 Hz, or even up to 500 Hz, corresponding to a very short scanning time for a single line. When the refresh rate is 500 Hz, the scanning time for a single line is only 1.8 μs. If a common electrode voltage cannot be restored after being coupled with a data voltage on a data line, it will lead to residual images on the line.

### SUMMARY

In a first aspect, embodiments of the present disclosure provide a display substrate, including a connection structure, a first common electrode, a second common electrode, a first conductive layer, and a second conductive layer; the connection structure includes a first connection portion, a second connection portion, and a conducting portion;
the first connection portion is electrically connected to the first common electrode through a first via-hole, and the second connection portion is electrically connected to the second common electrode through a second via-hole;
the conducting portion includes a first conducting sub-portion and a second conducting sub-portion; the first connection portion is electrically connected to the second connection portion through the first conducting sub-portion, and the first connection portion is electrically connected to the second connection portion through the second conducting sub-portion;
the first conducting sub-portion is located in the first conductive layer, and the second conducting sub-portion is located in the second conductive layer;
a length-width ratio of the first via-hole is X1, and a length-width ratio of the second via-hole is X2, with X1<1<X2;
the length-width ratio of the first via-hole is a ratio of the maximum length of the first via-hole along a first direction to the maximum width of the first via-hole along a second direction, the length-width ratio of the second via-hole is a ratio of the maximum length of the second via-hole along the first direction to the maximum width of the second via-hole along the second direction;
the first direction intersects with the second direction.

Optionally, conductivity of the first conductive layer is lower than conductivity of the second conductive layer.

Optionally, the first connection portion includes a first connection part and a second connection part; the first connection part is electrically connected to the first common electrode and the second connection part through the first via-hole;
the second connection portion includes a third connection part and a fourth connection part, the third connection part is electrically connected to the second common electrode and the fourth connection part through the second via-hole;
the first connection part is electrically connected to the third connection part through the first conducting sub-portion, and the second connection part is electrically connected to the fourth connection part through the second conducting sub-portion.

Optionally, the display substrate according to at least one embodiment of the present disclosure further includes a base substrate, the connection structure is on the base substrate; the first via-hole includes a first via-hole portion and a second via-hole portion arranged along the second direction;
an orthographic projection of the first via-hole portion on the base substrate does not overlap with an orthographic projection of the second connection part on the base substrate; the orthographic projection of the first via-hole portion on the base substrate is within an orthographic projection of the first common electrode on the base substrate;
an orthographic projection of the second via-hole portion on the base substrate is within the orthographic projection of the first common electrode on the base substrate, and the orthographic projection of the second via-hole portion on the base substrate is within the orthographic projection of the second connection part on the base substrate;
the orthographic projection of the second connection part on the base substrate overlaps at least partially with the orthographic projection of the first common electrode on the base substrate.

Optionally, the display substrate according to at least one embodiment of the present disclosure further includes a third conductive layer;
the first common electrode is located in the third conductive layer, the first connection part is located in the first conductive layer, and the second connection part is located in the second conductive layer.

Optionally, the display substrate according to at least one embodiment of the present disclosure further includes a base substrate; the connection structure is on the base substrate; the second via-hole includes a third via-hole portion and a fourth via-hole portion arranged along the first direction;
an orthographic projection of the third via-hole portion on the base substrate does not overlap with an orthographic projection of the fourth connection part on the base substrate; the orthographic projection of the third via-hole portion on the base substrate is within an orthographic projection of the third connection part on the base substrate;
an orthographic projection of the fourth via-hole portion on the base substrate is within the orthographic projection of the fourth connection part on the base substrate; the orthographic projection of the fourth via-hole portion on the base substrate is within the orthographic projection of the third connection part on the base substrate;
the orthographic projection of the fourth connection part on the base substrate overlaps at least partially with an orthographic projection of the second common electrode on the base substrate.

Optionally, the display substrate according to at least one embodiment of the present disclosure further includes a fourth conductive layer; the second common electrode is located in the fourth conductive layer, the third connection part is located in the first conductive layer, and the fourth connection part is located in the second conductive layer.

Optionally, X1 is less than or equal to 0.8, and X2 is greater than or equal to 1.2.

Optionally, X1/X2 is greater than or equal to 0.3 and less than or equal to 0.6.

Optionally, a distance between a first edge of the orthographic projection of the second via-hole portion on the base substrate and a second edge of the orthographic projection of the second connection part on the base substrate is greater than a first distance, and the first distance is greater than or equal to 1.9 μm but less than or equal to 2.3 μm,
the first edge is opposite to the second edge.

Optionally, the shortest distance along the second direction between an edge of the orthographic projection of the first via-hole portion on the base substrate and an edge of the orthographic projection of the second connection part on the base substrate is greater than a second distance, and the second distance is greater than or equal to 1.9 μm but less than or equal to 2.3 μm.

Optionally, a length of the second via-hole portion along the second direction is greater than a first length, and the first length is greater than or equal to 3.9 μm and less than or equal to 4.3 μm.

Optionally, a distance between an edge of the orthogonal projection of the first via-hole on the base substrate and an edge of the orthogonal projection of the first connection part on the base substrate is greater than a third distance, and the third distance is greater than or equal to 1.9 μm but less than or equal to 2.3 μm.

Optionally, a length of the first via-hole along the first direction is greater than a second length, and the second length is greater than or equal to 3.8 μm but less than or equal to 4.2 μm.

Optionally, a distance between a third edge of the orthogonal projection of the fourth via-hole portion on the base substrate and a fourth edge of the orthogonal projection of the fourth connection part on the base substrate is greater than a fourth distance, and the fourth distance is greater than or equal to 1.9 μm but less than or equal to 2.3 μm;
the third edge is opposite to the fourth edge.

Optionally, the shortest distance along the second direction between an edge of the orthographic projection of the third via-hole portion on the base substrate and an edge of the orthographic projection of the fourth connection part on the base substrate is greater than a fifth distance, and the fifth distance is greater than or equal to 1.9 μm but less than or equal to 2.3 μm.

Optionally, a length of the fourth via-hole portion along the first direction is greater than a third length, and the third length is greater than or equal to 3.9 μm and less than or equal to 4.3 μm.

Optionally, the shortest distance along the first direction between an edge of the orthographic projection of the second via-hole on the base substrate and an edge of the orthographic projection of the third connection part on the base substrate is greater than a sixth distance, and the sixth distance is greater than or equal to 1.9 μm but less than or equal to 2.3 μm.

Optionally, a length of the second via-hole along the second direction is greater than a fourth length, and the fourth length is greater than or equal to 3.8 μm but less than or equal to 4.2 μm.

Optionally, a length of the orthographic projection of the first via-hole portion on the base substrate along the first direction is greater than a length of the orthographic projection of the second via-hole portion on the base substrate along the first direction; or,
the length of the orthographic projection of the first via-hole portion on the base substrate along the first direction is smaller than the length of the orthographic projection of the second via-hole portion on the base substrate along the first direction.

Optionally, a length of the third via-hole portion along the second direction is greater than a length of the fourth via-hole portion along the second direction; or,
the length of the third via-hole portion along the second direction is smaller than the length of the fourth via-hole portion along the second direction.

Optionally, the display substrate according to at least one embodiment of the present disclosure further includes a base substrate and a gate line on the base substrate;
there is a first overlapping region between an orthographic projection of the gate line on the base substrate and an orthographic projection of the first conducting sub-portion of the connection structure on the base substrate;
there is a second overlapping region between the orthographic projection of the gate line on the base substrate and an orthographic projection of the second conducting sub-portion of the connection structure on the base substrate;
the area of the first overlapping region is smaller than the area of the second overlapping region.

Optionally, the display substrate according to at least one embodiment of the present disclosure further includes a base substrate, and a pixel electrode, a data line, a gate line, and a switch transistor on the base substrate;
the gate line includes a first gate line portion and a second gate line portion that are interconnected with each other; the first gate line portion is reused as the gate electrode of the switch transistor;
a first electrode of the switch transistor is electrically connected to the data line;
a second electrode of the switch transistor includes a transfer portion, a first electrode portion, and a second electrode portion; the transfer portion is electrically connected to the pixel electrode, the first electrode portion is on a first side of the transfer portion, and the second electrode portion is on a second side of the transfer portion, where the first side and the second side are opposite sides;
an orthographic projection of the first electrode portion on the base substrate overlaps at least partially with an orthographic projection of the first gate line portion on the base substrate;
an orthographic projection of the second electrode portion on the base substrate overlaps at least partially with an orthographic projection of the second gate line portion on the base substrate.

Optionally, the display substrate according to at least one embodiment of the present disclosure further includes a base substrate; the display substrate includes a first transparent conductive layer, a gate electrode layer, a source drain electrode layer, and a second transparent conductive layer arranged in a direction away from the base substrate in sequence;
the first conductive layer is the second transparent conductive layer, and the second conductive layer is the source drain electrode layer.

In a second aspect, the embodiments of the present disclosure provide a display device including the foregoing display substrate.

### BRIEF DESCRIPTION OF THE DRAWINGS

FIG. 1 is a layout diagram of a connection structure according to at least one embodiment of the present disclosure;

FIG. 2 is a layout diagram of a first transparent conductive layer in FIG. 1;

FIG. 3 is a layout diagram of a gate electrode layer in FIG. 1;

FIG. 4 is a layout diagram of a source drain electrode layer in FIG. 1;

FIG. 5 is a layout diagram of a second transparent conductive layer in FIG. 1;

FIG. 6 is a cross-sectional view of A-A′ in FIG. 1;

FIG. 7 is a cross-sectional view of B-B′ in FIG. 1;

FIG. 8A is an enlarged schematic diagram of a first via-hole in FIG. 1;

FIG. 8B is an enlarged schematic diagram of the first via-hole in FIG. 1;

FIG. 9A is an enlarged schematic diagram of a second via-hole in FIG. 1;

FIG. 9B is an enlarged schematic diagram of the second via-hole in FIG. 1;

FIG. 10 is a structural diagram of the first via-hole according to at least one embodiment;

FIG. 11 is a structural diagram of the first via-hole according to at least one embodiment;

FIG. 12 is a structural diagram of the second via-hole according to at least one embodiment;

FIG. 13 is a structural diagram of a third via-hole according to at least one embodiment;

FIG. 14 is a layout diagram of a display substrate according to at least one embodiment of the present disclosure;

FIG. 15 is a layout diagram of a first transparent conductive layer in FIG. 14;

FIG. 16 is a layout diagram of a gate electrode layer in FIG. 14;

FIG. 17 is a layout diagram of a source drain electrode layer in FIG. 14;

FIG. 18 is a layout diagram of a second transparent conductive layer in FIG. 14;

FIG. 19 is a layout diagram of the gate electrode layer in FIG. 14;

FIG. 20 is a layout diagram of the source drain electrode layer in FIG. 14;

FIG. 21 is a stacked diagram of the gate electrode layer and the second transparent conductive layer in FIG. 14;

FIG. 22 is a stacked diagram of the gate electrode layer and the source drain electrode layer in FIG. 14;

FIG. 23 is a structural diagram of the display substrate according to at least one embodiment of the present disclosure;

FIG. 24 is a structural diagram of a base substrate and the first transparent conductive layer included in the display substrate according to at least one embodiment of the present disclosure;

FIG. 25 is a structural diagram of the base substrate, the first transparent conductive layer and the gate electrode layer included in the display substrate according to at least one embodiment of the present disclosure;

FIG. 26 is a structural diagram of the base substrate, the first transparent conductive layer, the gate electrode layer, a gate insulation layer, a semiconductor layer and the source drain electrode layer included in the display substrate according to at least one embodiment of the present disclosure;

FIG. 27 is a structural diagram of the base substrate, the first transparent conductive layer, the gate electrode layer, a gate insulation layer, a semiconductor layer, the source drain electrode layer and a passivation layer included in the display substrate according to at least one embodiment of the present disclosure; and

FIG. 28 is a structural diagram of the base substrate, the first transparent conductive layer, the gate electrode layer, a gate insulation layer, a semiconductor layer, the source drain electrode layer, a passivation layer and the second transparent conductive layer included in the display substrate according to at least one embodiment of the present disclosure.

### DETAILED DESCRIPTION

The technical solutions in the embodiments of the present disclosure will be described clearly and completely below with reference to the drawings in the embodiments of the present disclosure, apparently, the described embodiments are part of the embodiments of the present disclosure, rather than all of embodiments. Based on the embodiments in the present disclosure, all other embodiments obtained by those ordinarily skilled in the art without paying creative efforts shall fall within the protection scope of the present disclosure.

Transistors used in all embodiments of the present disclosure can be thin film transistors, field-effect transistors, or other elements with similar characteristics. In the embodiments of the present disclosure, in order to distinguish between two electrodes of a transistor except for a gate electrode, one electrode is called a first electrode and the other electrode is called a second electrode.

In practical operation, when the transistor is a thin film transistor or field-effect transistor, the first electrode can be a drain electrode, and the second electrode can be a source electrode; or, the first electrode can be the source electrode, and the second electrode can be the drain electrode.

The display substrate described in the embodiments of the present disclosure includes a connection structure, a first common electrode, a second common electrode, a first conductive layer, and a second conductive layer. The connection structure includes a first connection portion, a second connection portion, and a conducting portion.

The first connection portion is electrically connected to the first common electrode through a first via-hole, and the second connection portion is electrically connected to the second common electrode through a second via-hole.

The conducting portion includes a first conducting sub-portion and a second conducting sub-portion. The first connection portion is electrically connected to the second connection portion through the first conducting sub-portion, and the first connection portion is electrically connected to the second connection portion through the second conducting sub-portion.

The first conducting sub-portion is located in the first conductive layer, and the second conducting sub-portion is located in the second conductive layer;
A length-width ratio of the first via-hole is X1, and a length-width ratio of the second via-hole is X2, with X1<1<X2.

The length-width ratio of the first via-hole is a ratio of the maximum length of the first via-hole along a first direction to the maximum width of the first via-hole along a second direction. The length-width ratio of the second via-hole is a ratio of the maximum length of the second via-hole along the first direction to the maximum width of the second via-hole along the second direction;
The first direction intersects with the second direction.

In the connection structure described in the embodiments of the present disclosure, the first connection portion is electrically connected to the second connection portion through the first conducting sub-portion and the second conducting sub-portion, respectively. The second conducting sub-portion can reduce resistance of the connection portion, increase uniformity of a common electrode network of the entire display panel, and enhance restoring force of the common electrode voltage after being pulled by data voltage coupling.

In at least one embodiment of the present disclosure, the first common electrode may be located in a gate electrode layer, the second common electrode may be located in a first transparent conductive layer, the first conducting sub-portion may be located in a second transparent conductive layer, and the second conducting sub-portion may be located in a source drain electrode layer, but not limited to this.

Optionally, the first transparent conductive layer can be a first ITO (indium tin oxide) layer, and the second transparent conductive layer can be a second ITO layer.

In related technologies, in high refresh rate products, such as in esports display products, the refresh rate can reach 240 Hz or even 500 Hz, corresponding to a very short scanning time for a single line. When the refresh rate is 500 Hz, the scanning time for a single line is only 1.8 μs. If the common electrode voltage cannot be restored after being coupled with the data voltage on the data line, it will lead to residual images on the line. In the relevant connection structures, the first connection portion and the second connection portion are electrically connected through the first conducting sub-portion. The first conducting sub-portion can be located, for example, in the second transparent conductive layer, which has a high resistivity and may result in M24 defects. Based on this, in at least one embodiment of the present disclosure, the first connection portion is electrically connected to the second connection portion through the first conducting sub-portion, and the first connection portion is electrically connected to the second connection portion through the second conducting sub-portion, which can reduce the resistance of the conducting portion.

Optionally, conductivity of the first conductive layer is lower than conductivity of the second conductive layer.

In at least one embodiment of the present disclosure, the resistivity of the second transparent conductive layer is relatively high, while the resistivity of the source drain electrode layer is relatively low. By jointly connection the first common electrode and the second common electrode through the second transparent conductive layer and the source drain electrode layer, the uniformity of the resistance of the common electrodes of the entire display panel can be improved.

Optionally, the first direction can be horizontal, and the second direction can be vertical, but not limited to this.

Optionally, the first connection portion includes a first connection part and a second connection part; the first connection part is electrically connected to the first common electrode and the second connection part through the first via-hole;
The second connection portion includes a third connection part and a fourth connection part, where the third connection part is electrically connected to the second common electrode and the fourth connection part through the second via-hole;
The first connection part is electrically connected to the third connection part through the first conducting sub-portion, and the second connection part is electrically connected to the fourth connection part through the second conducting sub-portion.

In at least one embodiment of the present disclosure, the first connection part and the first common electrode may be located in different conductive layers, the first connection part and the second connection part may be located in different conductive layers, the third connection part and the second common electrode may be located in different conductive layers, and the third connection part and the fourth connection part may be located in different conductive layers.

In at least one embodiment of the present disclosure, the first connection part may be located in the second transparent conductive layer, the second connection part may be located in the source drain electrode layer, the third connection part may be located in the second transparent conductive layer, and the fourth connection part may be located in the source drain electrode layer, but not limited to this.

In at least one embodiment of the present disclosure, the display substrate may further include a base substrate; the connection structure is on the base substrate; the first via-hole includes a first via-hole portion and a second via-hole portion arranged along the second direction;
An orthographic projection of the first via-hole portion on the base substrate does not overlap with an orthographic projection of the second connection part on the base substrate; The orthographic projection of the first via-hole portion on the base substrate is within an orthographic projection of the first common electrode on the base substrate;
An orthographic projection of the second via-hole portion on the base substrate is within the orthographic projection of the first common electrode on the base substrate, and the orthographic projection of the second via-hole portion on the base substrate is within the orthographic projection of the second connection part on the base substrate;
The orthographic projection of the second connection part on the base substrate overlaps at least partially with the orthographic projection of the first common electrode on the base substrate.

In specific implementation, the first via-hole can be designed as a half via-hole, and the first via-hole can be upper and lower half via-holes. The lower half of the first via-hole is used for electrically connection the first common electrode and the first connection part, and the upper half of the first via-hole is used for electrically connection the first connection part and the second connection part; At least one embodiment of the present disclosure can facilitate the diffusion of PI (polyimide) liquid and improve M24 defects (M24 defects can be Mura (uneven display) type defects) by adopting a half via-hole design for the first via-hole.

In at least one embodiment of the present disclosure, the lower half of the first via-hole can be punched on the gate electrode layer, the upper half of the first via-hole can be punched on the source drain electrode layer, and the middle bridging part of the first via-hole can be a source drain metal pattern located in the source drain electrode layer, but not limited to this.

M24 defects can be Mura defects caused by abnormal PI around a via-hole where there is no PI liquid, or periodic Mura defects caused by uneven diffusion of PI liquid at a via-hole. When the via-hole adopts a half via-hole design, it is conducive to the diffusion of PI liquid.

Optionally, the display substrate may further include a third conductive layer; the first common electrode is located in the third conductive layer, the first connection part is located in the first conductive layer, and the second connection part is located in the second conductive layer.

In at least one embodiment of the preset disclosure, the third conductive layer may be the gate electrode layer, the first conductive layer may be the second transparent conductive layer, and the second conductive layer may be the source drain electrode layer, but not limited to this.

In at least one embodiment of the present disclosure, the display substrate further includes a base substrate; the connection structure is on the base substrate; the second via-hole includes a third via-hole portion and a fourth via-hole portion arranged along the first direction;
An orthographic projection of the third via-hole portion on the base substrate does not overlap with an orthographic projection of the fourth connection part on the base substrate; the orthographic projection of the third via-hole portion on the base substrate is within an orthographic projection of the third connection part on the base substrate;
An orthographic projection of the fourth via-hole portion on the base substrate is within the orthographic projection of the fourth connection part on the base substrate; the orthographic projection of the fourth via-hole portion on the base substrate is within the orthographic projection of the third connection part on the base substrate;
The orthographic projection of the fourth connection part on the base substrate overlaps at least partially with an orthographic projection of the second common electrode on the base substrate.

In specific implementation, the second via-hole can be designed as a half via-hole, and the second via-hole can be left and right via-holes. The left half of the second via-hole can be used for electrically connection the second common electrode and the third connection part, and the right half of the second via-hole can be used for electrically connection the third connection part and the fourth connection part. At least one embodiment of the present disclosure can facilitate the diffusion of PI liquid and improve M24 defects (M24 defects can be Mura type defects) by adopting a half via-hole design for the second via-hole.

In at least one embodiment of the present disclosure, the left half of the second via-hole can be punched on the second common electrode, the right half of the second via-hole can be punched on the source drain electrode layer, and the middle bridging part of the second via-hole can be a source drain metal pattern, but not limited to this.

Optionally, the display substrate may further include a fourth conductive layer; the second common electrode is located in the fourth conductive layer, the third connection part is located in the first conductive layer, and the fourth connection part is located in the second conductive layer.

In at least one embodiment of the preset disclosure, the fourth conductive layer may be the first transparent conductive layer, but not limited to this.

Optional, X1 is less than or equal to 0.8, and X2 is greater than or equal to 1.2. Furthermore, X1 is less than or equal to 0.64, and X2 is greater than or equal to 1.55.

In at least one embodiment disclosed herein, X1/X2 is greater than or equal to 0.3 and less than or equal to 0.6, for example, X/X2 can be 0.3, 0.35, 0.4, 0.45, 0.5, 0.55, or 0.6.

Optionally, a distance between a first edge of the orthographic projection of the second via-hole portion on the base substrate and a second edge of the orthographic projection of the second connection part on the base substrate is greater than a first distance, and the first distance is greater than or equal to 1.9 μm but less than or equal to 2.3 μm. For example, the first distance can be 1.9 μm, 2 μm, 2.1 μm, 2.2 μm or 2.3 μm, so that the first via-hole can be punched on the second conductive layer;
The first edge is opposite to the second edge.

Optionally, the shortest distance in the second direction between the edge of the orthographic projection of the first via-hole portion on the base substrate and the edge of the orthographic projection of the second connection part on the base substrate is greater than a second distance, and the second distance is greater than or equal to 1.9 μm but less than or equal to 2.3 μm. For example, the second distance can be 1.9 μm, 2 μm, 2.1 μm, 2.2 μm or 2.3 μm to ensure the formation of a half via-hole.

Optionally, the length of the second via-hole portion along the second direction is greater than a first length, and the first length is greater than or equal to 3.9 μm and less than or equal to 4.3 μm. For example, the first length can be 3.9 μm, 4 μm, 4.1 μm, 4.2 μm or 4.3 μm, so that even if the second connection part is moved up a certain distance due to process deviations during the production of the display substrate, the overlap distance between the second conductive layer and the first via-hole can reach more than 2 μm, ensuring that it can be electrically connected to the second conductive layer through the first via-hole.

In at least one embodiment of the present disclosure, a distance between the edge of the orthogonal projection of the first via-hole on the base substrate and the edge of the orthogonal projection of the first connection part on the base substrate is greater than a third distance, and the third distance is greater than or equal to 1.9 μm but less than or equal to 2.3 μm. For example, the third distance can be 1.9 μm, 2 μm. 2.1 μm, 2.2 μm or 2.3 μm to ensure that the first conductive layer wraps around the first via-hole, preventing the first via-hole from being exposed and corroded by water vapor and air intrusion.

Optionally, the length of the first via-hole along the first direction is greater than a second length, and the second length is greater than or equal to 3.8 μm but less than or equal to 4.2 μm. For example, the second length can be 3.8 μm, 3.9 μm, 4 μm, 4.1 μm or 4.2 μm.

In at least one embodiment of the present disclosure, a distance between a third edge of the orthogonal projection of the fourth via-hole portion on the base substrate and a fourth edge of the orthogonal projection of the fourth connection part on the base substrate is greater than a fourth distance, and the fourth distance is greater than or equal to 1.9 μm but less than or equal to 2.3 μm. For example, the fourth distance can be 1.9 μm, 2 μm. 2.1 μm, 2.2 μm or 2.3 μm to enable the second via-hole can be punched on the second conductive layer;
The third edge is opposite to the fourth edge.

In at least one embodiment of the present disclosure, the shortest distance along the second direction between the edge of the orthographic projection of the third via-hole portion on the base substrate and the edge of the orthographic projection of the fourth connection part on the base substrate is greater than a fifth distance, and the fifth distance is greater than or equal to 1.9 μm but less than or equal to 2.3 μm. For example, the fifth distance can be 1.9 μm, 2 μm, 2.1 μm, 2.2 μm or 2.3 μm to ensure the formation of a half via-hole.

Optionally, the length of the fourth via-hole portion along the first direction is greater than a third length, and the third length is greater than or equal to 3.9 μm and less than or equal to 4.3 μm. For example, the first length can be 3.9 μm, 4 μm, 4.1 μm, 4.2 μm or 4.3 μm, so that even if the fourth connection part is shifted to the right by a certain distance due to process deviations during the production of the display substrate, the overlap distance between the second conductive layer and the second via-hole can reach more than 2 μm, ensuring that it can be electrically connected to the second conductive layer through the second via-hole.

In at least one embodiment of the present disclosure, the shortest distance along the first direction between the edge of the orthographic projection of the second via-hole on the base substrate and the edge of the orthographic projection of the third connection part on the base substrate is greater than a sixth distance, and the sixth distance is greater than or equal to 1.9 μm but less than or equal to 2.3 μm. For example, the fifth distance can be 1.9 μm, 2 μm, 2.1 μm, 2.2 μm or 2.3 μm to ensure that the first conductive layer wraps around the second via-hole, preventing the second via-hole from being exposed and corroded by water vapor and air intrusion.

Optionally, the length of the second via-hole along the second direction is greater than a fourth length, and the fourth length is greater than or equal to 3.8 μm but less than or equal to 4.2 μm. For example, the second length can be 3.8 μm, 3.9 μm, 4 μm, 4.1 μm or 4.2 μm.

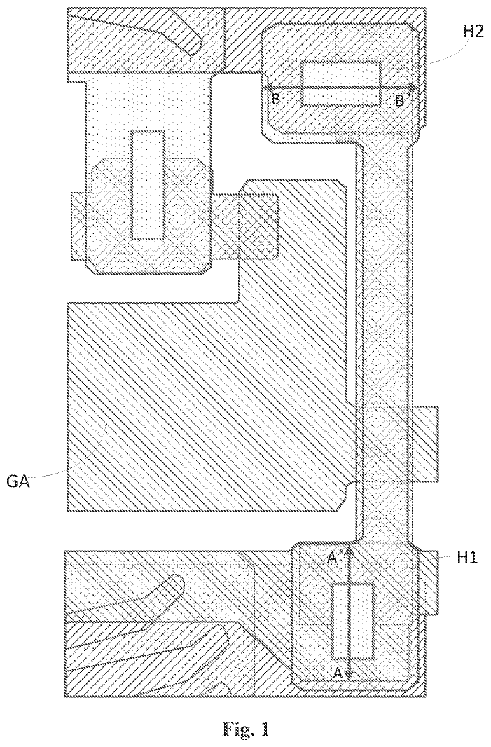

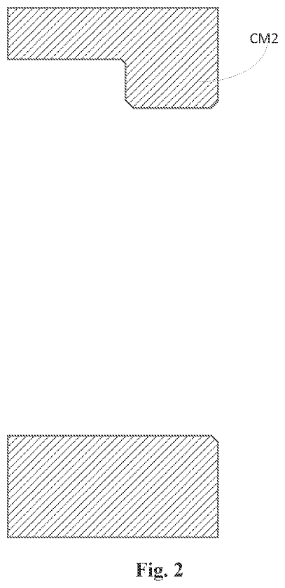

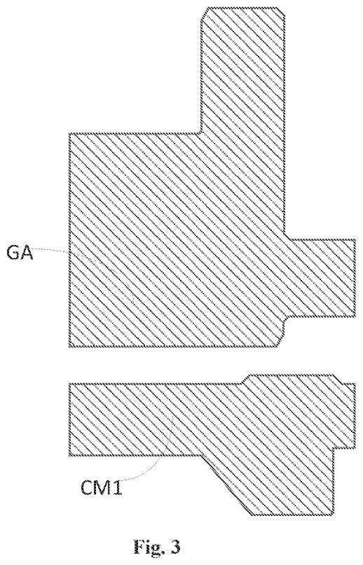

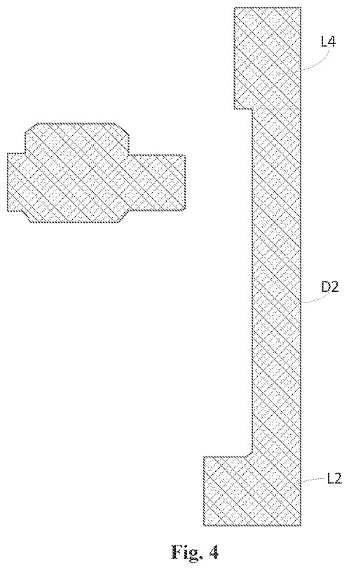

FIG. 1 is a layout diagram of the connection structure according to at least one embodiment of the present disclosure, FIG. 2 is a layout diagram of the first transparent conductive layer in FIG. 1, FIG. 3 is a layout diagram of the gate electrode layer in FIG. 1, FIG. 4 is a layout diagram of the source drain electrode layer in FIG. 1, and FIG. 5 is a layout diagram of the second transparent conductive layer in FIG. 1.

In FIG. 3, a line labeled GA is a gate line.

As shown in FIG. 1 to FIG. 5, the first common electrode CMI is electrically connected to the first connection part L1 and the second connection part L2 respectively through the first via-hole H1;

The second common electrode CM2 is electrically connected to the third connection part L3 and the fourth connection part L4 respectively through the second via-hole H2;
The first common electrode CMI is located in the gate electrode layer, the first connection part L1 is located in the second transparent conductive layer, the second connection part L2 is located in the source drain electrode layer, the second common electrode CM2 is located in the first transparent conductive layer, the third connection part L3 is located in the second transparent conductive layer, and the fourth connection part L4 is located in the source drain electrode layer.

The first connection part L1 is electrically connected to the third connection part L3 through the first conducting sub-portion D1, and the second connection part L2 is electrically connected to the fourth connection part L4 through the second conducting sub-portion D2.

The first conducting sub-portion D1 is located in the second transparent conductive layer, and the second conducting sub-portion D2 is located in the source drain electrode layer, but not limited to this.

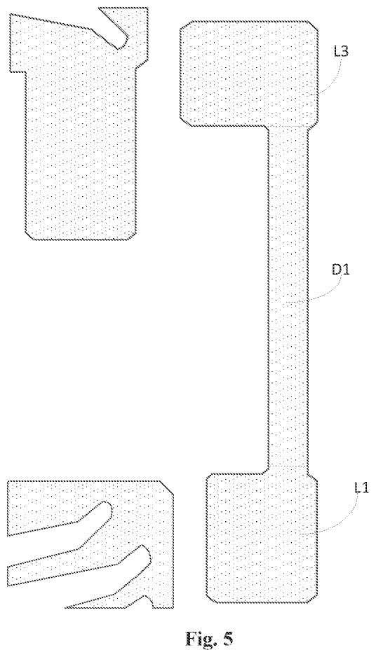

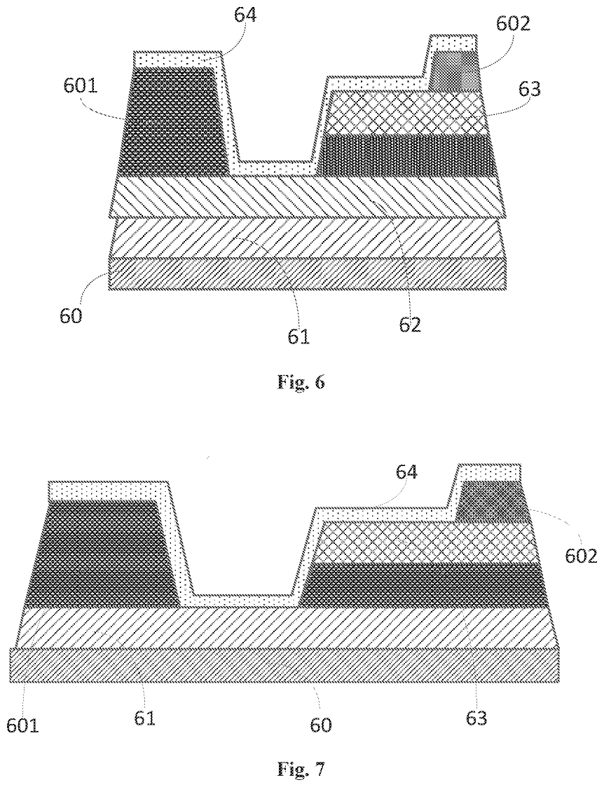

FIG. 6 is a cross-sectional view of A-A′ in FIG. 1, and FIG. 7 is a cross-sectional view of B-B′ in FIG. 1.

In FIG. 6 and FIG. 7, a label 60 is the base substrate, a label 61 is the first transparent conductive layer, a label 62 is the gate electrode layer, a label 63 is the source drain electrode layer, and a label 64 is the second transparent conductive layer.

A label 601 is the gate insulation layer, and a label 602 is the passivation layer.

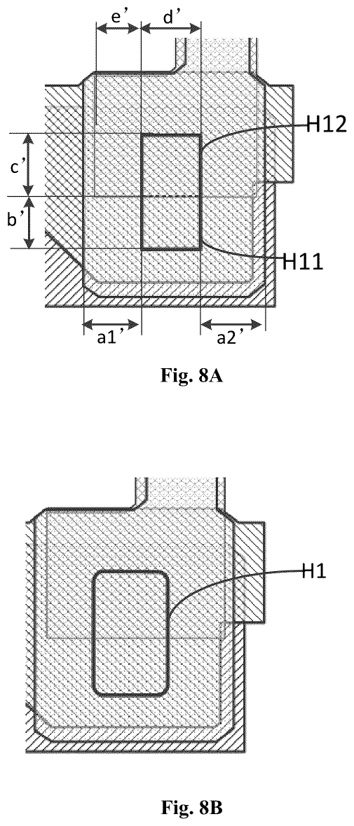

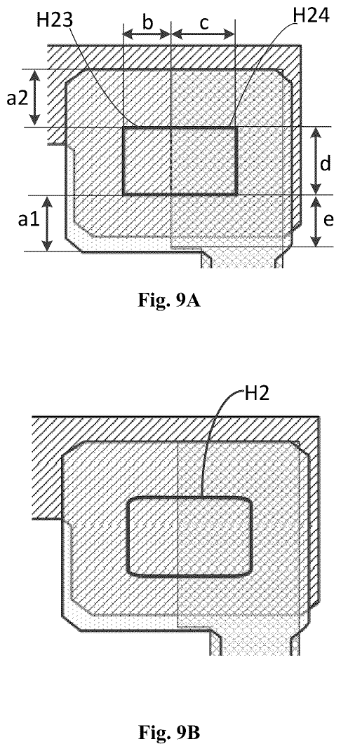

FIG. 8A is an enlarged schematic diagram of the first via-hole in FIG. 1, and FIG. 9A is an enlarged schematic diagram of the second via-hole in FIG. 1.

As shown in FIG. 8A, the first via-hole H1 includes a first via-hole portion H11 and a second via-hole portion H12 arranged vertically.

As shown in FIG. 1 to FIG. 8A, the orthogonal projection of the first via-hole portion H11 on the base substrate does not overlap with the orthogonal projection of the second connection part L2 on the base substrate; the orthogonal projection of the first via-hole portion H11 on the base substrate is within the orthogonal projection of the first common electrode CM1 on the base substrate.

The orthogonal projection of the second via-hole portion H12 on the base substrate is within the orthogonal projection of the first common electrode CMI on the base substrate, and the orthogonal projection of the second via-hole portion H12 on the base substrate is within the orthogonal projection of the second connection part L2 on the base substrate;

The orthogonal projection of the second connection part L2 on the base substrate overlaps at least partially with the orthogonal projection of the first common electrode CMI on the base substrate.

As shown in FIG. 8A, a label b′ is a vertical distance between the lower edge of the orthographic projection of the first via-hole portion H11 on the base substrate and the lower edge of the orthographic projection of the second connection part L2 on the base substrate, where b′ is greater than 2.1 μm to ensure the formation of upper and lower half via-holes;
A label c′ is a length of the second via-hole portion H12 along the vertical direction, where c′ is greater than 4.1 μm to ensure that even if the second connection part L2 is moved up 2. 1 μm due to process deviations during the production of the display substrate, the overlap distance between the source drain electrode layer and the first via-hole H1 can reach more than 2 μm, ensuring that it can be electrically connected to the source drain electrode layer through the first via-hole H1.

A label a1′ is the shortest distance between the left edge of the orthographic projection of the first via-hole H1 on the base substrate and the left edge of the orthographic projection of the first connection part L1 on the base substrate, and a label a2′ is the shortest distance between the right edge of the orthographic projection of the first via-hole H1 on the base substrate and the right edge of the orthographic projection of the first connection part L1 on the base substrate, where a1′ and a2′ are both greater than 2.1 μm to ensure that the second transparent conductive layer can wrap around the via-hole, preventing the via-hole from being exposed and corroded by water vapor and air intrusion.

A label e′ is a horizontal distance between the left edge of the orthographic projection of the second via-hole portion H12 on the base substrate and the left edge of the orthographic projection of the second connection part L2 on the base substrate, where e′ is greater than 2.1 μm to ensure that the first via-hole H1 can be punched on the source drain electrode layer;
A label d′ is a length of the first via-hole H1 along the horizontal direction, where d′ is greater than 4 μm; but not limited to this.

In practical operation, the length of the first via-hole H1 along the horizontal direction needs to be set to be small to avoid affecting the pixel aperture rate.

In at least one embodiment shown in FIG. 8A, both the first edge and the second edge may be lower edges, but not limited to this.

In at least one embodiment shown in FIG. 8A, the first via-hole is a rectangular via-hole, but not limited to this. In practical operation, the first via-hole can be of other shapes.

As shown in FIG. 8B, the first via-hole H1 can be a circular rectangular via-hole, but not limited to this.

As shown in FIG. 1 to FIG. 9A, the second via-hole includes a third via-hole portion H23 and a fourth via-hole portion H24 arranged horizontally;

The orthographic projection of the third via-hole portion H23 on the base substrate does not overlap with the orthographic projection of the fourth connection part L4 on the base substrate; the orthographic projection of the third via-hole portion H3 on the base substrate is within the orthographic projection of the third connection part L3 on the base substrate.

The orthographic projection of the fourth via-hole portion H24 on the base substrate is within the orthographic projection of the fourth connection part L4 on the base substrate; The orthographic projection of the fourth via-bole portion H24 on the base substrate is within the orthographic projection of the third connection part L3 on the base substrate.

The orthographic projection of the fourth connection part L4 on the base substrate overlaps at least partially with the orthographic projection of the second common electrode CM2 on the base substrate.

As shown in FIG. 9A, a label b is a horizontal distance between the left edge of the orthogonal projection of the third via-hole portion H23 on the base substrate and the left edge of the orthogonal projection of the fourth connection part L4 on the base substrate, where b is greater than 2.1 μm to ensure the formation of left and right via-holes.

A label c is a length of the fourth via-hole portion H24 along the horizontal direction, where c is greater than 4.1 μm to ensure that even if the fourth connection part is shifted to the right by 2.1 μm due to process deviations during the production of the display substrate, the overlap distance between the source drain electrode layer and the second via-hole H2 can reach more than 2 μm, ensuring that it can be electrically connected to the source drain electrode layer through the second via-hole H2.

A label al is the shortest distance between the lower edge of the orthographic projection of the second via-hole H2 on the base substrate and the lower edge of the orthographic projection of the third connection part L3 on the base substrate, and a label a2 is the shortest distance between the upper edge of the orthographic projection of the second via-hole H2 on the base substrate and the upper edge of the orthographic projection of the third connection part L3 on the base substrate, where al and a2 are both greater than 2.1 μm to ensure that the second transparent conductive layer can wrap around the via-hole, preventing the via-hole from being exposed and corroded by water vapor and air intrusion.

A label e is the shortest vertical distance between the lower edge of the orthographic projection of the fourth via-hole portion H24 on the base substrate and the lower edge of the orthographic projection of the fourth connection part L4 on the base substrate, where e is greater than 2.1 μm to ensure that the second via-hole H2 can be punched on the source drain electrode layer.

A label d is a length of the second via-hole H2 along the vertical direction, where d is greater than 4 μm; but not limited to this.

In practical operation, the length of the second via-hole H2 along the vertical direction needs to be set to be small to avoid affecting the pixel aperture rate.

In at least one embodiment shown in FIG. 9A, both the third edge and the fourth edge may be left edges, but not limited to this.

In the embodiments of FIG. 1 to FIG. 9A, both the first via-hole H1 and the second via-hole H2 are rectangular via-holes, but not limited to them.

In at least one embodiment shown in FIG. 9A, the second via-hole is a rectangular via-hole, but not limited to this. In practical operation, the second via-hole can be of other shapes.

As shown in FIG. 9B, the second via-hole H2 can be a circular rectangular via-hole, but not limited to this.

In at least one embodiment of the present disclosure, the length of the orthographic projection of the first via-hole portion on the base substrate along the first direction is greater than the length of the orthographic projection of the second via-hole portion on the base substrate along the first direction; or,
the length of the orthographic projection of the first via-hole portion on the base substrate along the first direction is smaller than the length of the orthographic projection of the second via-hole portion on the base substrate along the first direction.

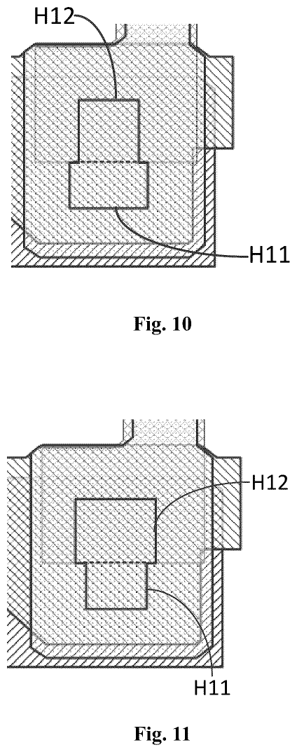

As shown in FIG. 10, the length of the orthographic projection of the first via-hole portion H11 on the base substrate along the horizontal direction is greater than the length of the orthographic projection of the second via-hole portion H12 on the base substrate along the horizontal direction.

As shown in FIG. 11, the length of the orthographic projection of the first via-hole portion H11 on the base substrate along the horizontal direction is smaller than the length of the orthographic projection of the second via-hole portion H12 on the base substrate along the horizontal direction.

In at least one embodiment of the present disclosure, the length of the third via-hole portion along the second direction is greater than the length of the fourth via-hole portion along the second direction; or,
the length of the third via-hole portion along the second direction is smaller than the length of the fourth via-hole portion along the second direction.

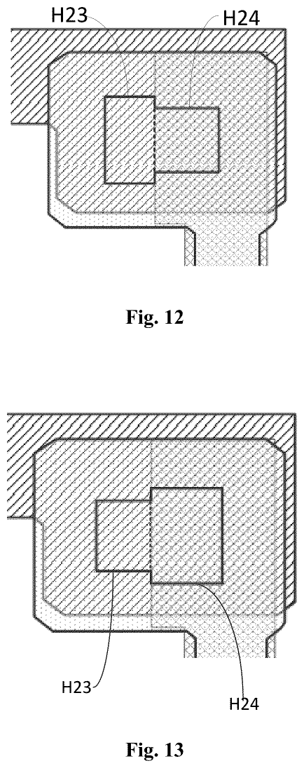

As shown in FIG. 12, the length of the third via-hole portion H23 along the vertical direction is greater than the length of the fourth via-hole portion H24 along the vertical direction.

As shown in FIG. 13, the length of the third via-hole portion H23 along the vertical direction is smaller than the length of the fourth via-hole portion H24 along the vertical direction.

In specific implementation, the first via-hole and the second via-hole can be “convex” shaped via-holes. Regardless of whether the PI liquid flows from narrow to wide or from wide to narrow, “convex” shaped via-holes are more conducive to the diffusion of PI liquid in the via-holes.

The display substrate according to the embodiments of the present disclosure includes a base substrate and a first common electrode, a second common electrode, and the foregoing connection structure on the base substrate;

The connection structure is used for electrically connection the first common electrode to the second common electrode.

The display substrate according to at least one embodiment of the present disclosure further includes a gate line on the base substrate;
There is a first overlapping region between the orthographic projection of the gate line on the base substrate and the orthographic projection of the first conducting sub-portion of the connection structure on the base substrate;
There is a second overlapping region between the orthographic projection of the gate line on the base substrate and the orthographic projection of the second conducting sub-portion of the connection structure on the base substrate;
The area of the first overlapping region is smaller than the area of the second overlapping region. Specifically, the area of the first overlapping region and the area of the second overlapping region are smaller than a first area, and the first area is greater than or equal to 14 μm² but less than or equal to 18 μm², for example, the first area can be 14 μm², 15 μm², 16 μm², 17 μm² or 18 μm² to reduce the parasitic capacitance between the gate line and the first conducting sub-portion, reduce the parasitic capacitance between the gate line and the second conducting sub-portion, and prevent an increase in load on the gate line.

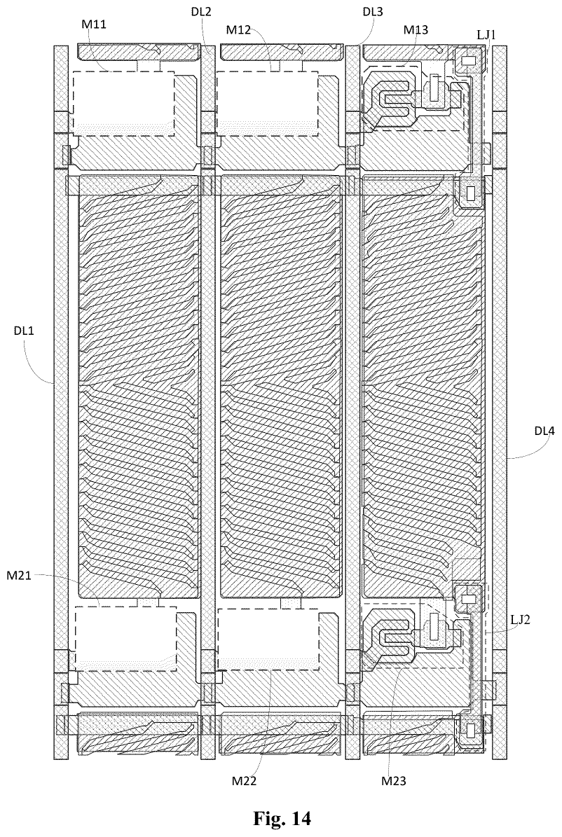

As shown in FIG. 14 to FIG. 18, the display substrate according to at least one embodiment of the present disclosure includes a base substrate, and a first row gate line GA1, a second row gate line GA2, a first row common electrode line CML1 and a second row second common electrode line CML2 on the base substrate, a first column data line DL1, a second column data line DL2, a third column data line DL3, a fourth column data line DL4, a first second-common electrode CM12, a second second-common electrode CM22, a third second-common electrode CM32, a first row first column switch transistor M11, a first row second column switch transistor M12, a first row third column switch transistor M13, a second row first column switch transistor M21, a second row second column switch transistor M22, a second row third column switch transistor M23, a first connection structure LJ1, a second connection structure LJ2, a first pixel electrode PJ1, a second pixel electrode PJ2 and a third pixel electrode PJ3;
The first row common electrode line CML1 is used as the first common electrode CM11, and the second row common electrode line CML2 is used as the second first-common electrode CM21;
CML1, CML2, GA1, and GA2 are all located in the gate electrode layer;
The first electrodes of DL1, DL2, DL3, DL4, M11, the second electrode of M11, the first electrode of M12, the second electrode of M12, the first electrode of M13, the second electrode of M13, the first electrode of M21, the second electrode of M21, the first electrode of M22, the second electrode of M22, the first electrode of M23, and the second electrode of M23 are all located in the source drain electrode layer;
CM12, CM22, and CM32 are all located in the first transparent conductive layer;
PJ1, PJ2, and PJ3 are all located in the second transparent conductive layer.

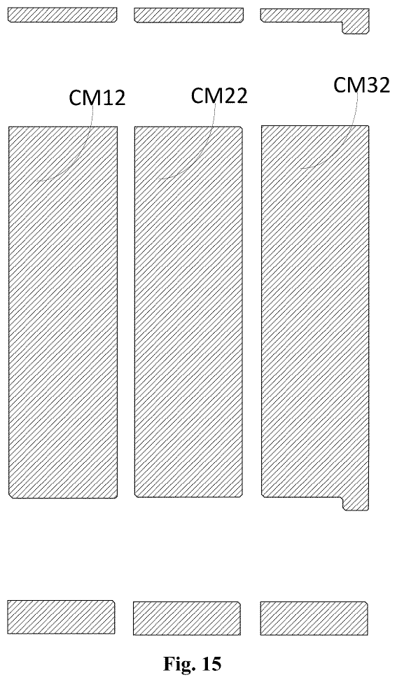

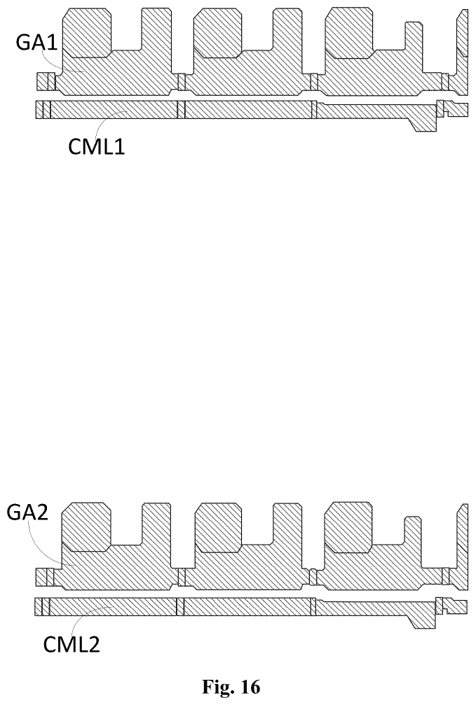

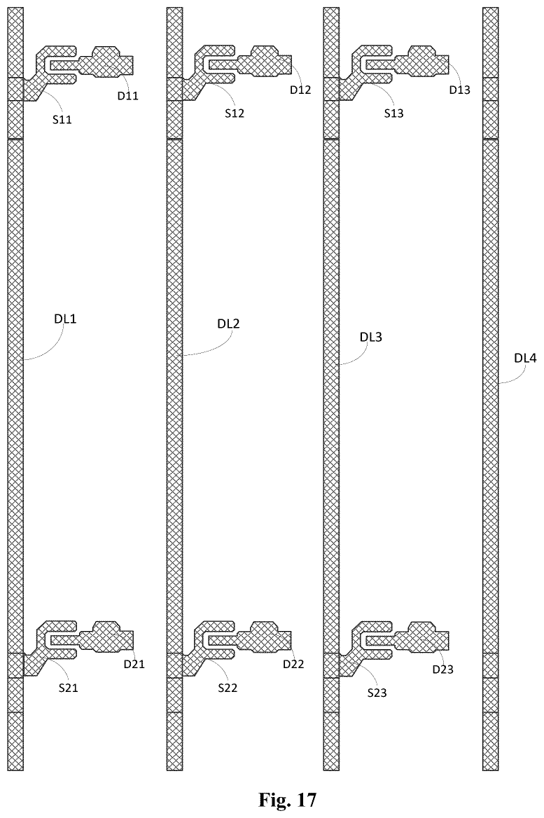

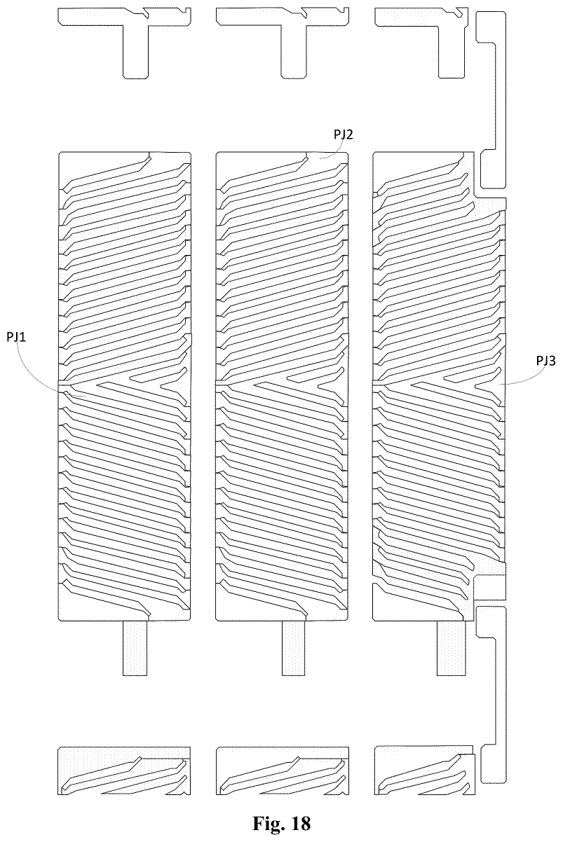

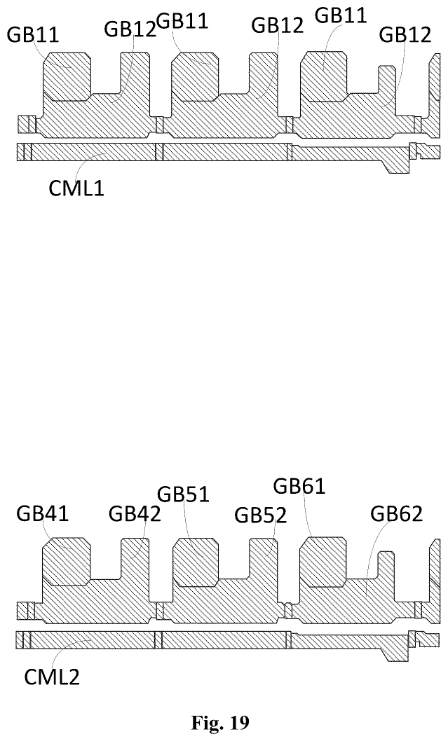

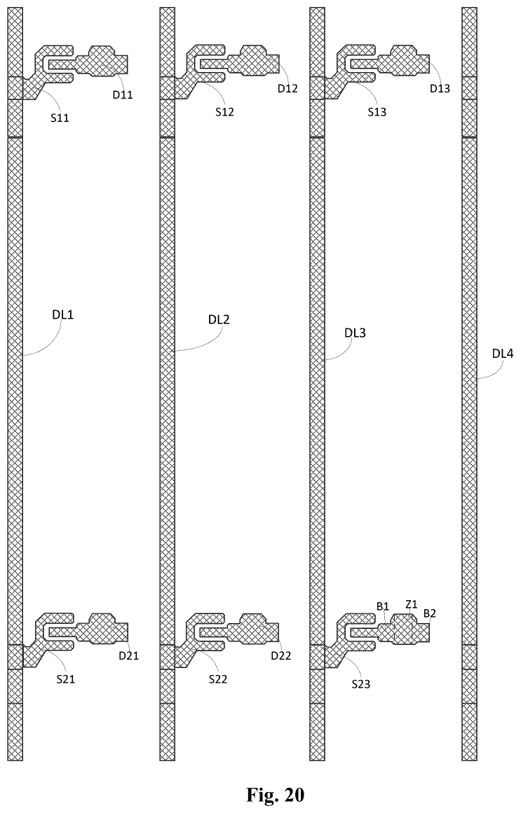

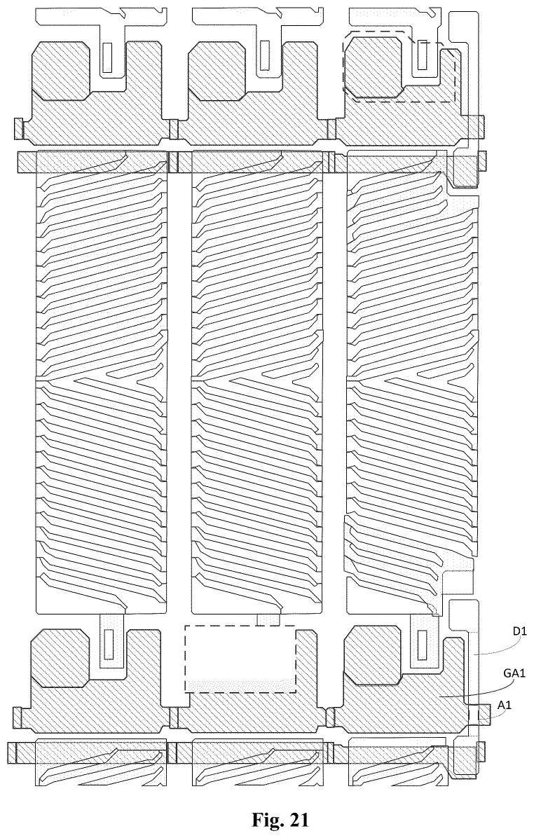

FIG. 14 is a layout diagram of the display substrate according to at least one embodiment of the present disclosure, FIG. 15 is a layout diagram of the first transparent conductive layer in FIG. 14, FIG. 16 is a layout diagram of the gate electrode layer in FIG. 14, FIG. 17 is a layout diagram of the source drain electrode layer in FIG. 14, and FIG. 18 is a layout diagram of the second transparent conductive layer in FIG. 14. FIG. 19 is a layout diagram of the gate electrode layer in FIG. 14, FIG. 20 is a layout diagram of the source drain electrode layer in FIG. 14, FIG. 21 is a stacked diagram of the gate electrode layer and the second transparent conductive layer in FIG. 14, and FIG. 22 is a stacked diagram of the gate electrode layer and the source drain electrode layer in FIG. 14.

The display substrate according to at least one embodiment of the present disclosure further includes a base substrate, and a pixel electrode, a data line, a gate line, and a switch transistor on the base substrate;
The gate line includes a first gate line portion and a second gate line portion that are interconnected with each other; the first gate line portion is reused as the gate electrode of the switch transistor;
The first electrode of the switch transistor is electrically connected to the data line;
The second electrode of the switch transistor includes a transfer portion, a first electrode portion, and a second electrode portion; the transfer portion is electrically connected to the pixel electrode, the first electrode portion is on a first side of the transfer portion, the second electrode portion is on a second side of the transfer portion, and the first side and the second side are opposite sides;
An orthographic projection of the first electrode portion on the base substrate overlaps at least partially with an orthographic projection of the first gate line portion on the base substrate;
An orthographic projection of the second electrode portion on the base substrate overlaps at least partially with an orthographic projection of the second gate line portion on the base substrate.

As shown in FIG. 14 to FIG. 18, the first electrode S11 of M11 is electrically connected to the first column data line DL1, while the first electrode S21 of M21 is electrically connected to the first column data line DL1;
The first electrode S12 of M12 is electrically connected to the second column data cable DL2, while the first electrode S22 of M22 is electrically connected to the second column data line DL2;
The first electrode S13 of M13 is electrically connected to the third column data line DL3, while the first electrode S23 of M23 is electrically connected to the third column data cable DL3;
As shown in FIG. 19, the first row gate line includes a first first-gate line portion GB11, a first second-gate line portion GB12, a second first-gate line portion GB21, a second second-gate line portion GB22, a third first-gate line portion GB31, and a third second-gate line portion GB32; the second row gate line includes a fourth first-gate gate line portion GB41, a fourth second-gate line portion GB22, a fifth first-gate line portion GB51, a fifth second-gate line portion GB52, a sixth first-gate line portion GB61, and a sixth second-gate line portion GB62 that are interconnected with each other,
GB11 is reused as the gate electrode of M11, GB12 is reused as the gate electrode of M12, GB13 is reused as the gate electrode of M13, GB21 is reused as the gate electrode of M21, GB22 is reused as the gate electrode of M22, and GB23 is reused as the gate electrode of M23.

As shown in FIG. 20, the second electrode of M23 includes the transfer portion Z1, the first electrode portion B1, and the second electrode portion B2.

The first electrode portion B1 is located on the left side of the transfer portion Z1, and the second electrode portion B2 is located on the right side of the transfer portion Z1.

As shown in FIG. 14 to FIG. 20, the orthographic projection of the first electrode portion B1 on the base substrate at least partially overlaps with the orthographic projection of GB61 on the base substrate, and the orthographic projection of the second electrode portion B2 on the base substrate at least partially overlaps with the orthographic projection of GB62 on the base substrate, so that even if the second row gate line GA2 is shifted to the right or left due to process deviations, Cgs can be roughly the same, where Cgs is the parasitic capacitance of the gate source.

As shown in FIG. 14 to FIG. 22, there is the first overlapping region A1 between the orthographic projection of the second row gate line GA2 on the base substrate and the orthographic projection of the first conducting sub-portion D1 included in the second connection structure on the base substrate. There is the second overlapping region A2 between the orthographic projection of the second row gate line GA2 on the base substrate and the orthographic projection of the second conducting sub-portion D2 included in the second connection structure on the base substrate.

The area of the first overlapping area A1 is less than 16 μm2, the area of the second overlapping area A2 is less than 16 μm2, in order to reduce the parasitic capacitance between the second row gate line GA2 and the first conducting sub-portion D1, reduce the parasitic capacitance between the second row gate line GA2 and the second conducting sub-portion D2, and prevent an increase in load on the second row gate line GA2.

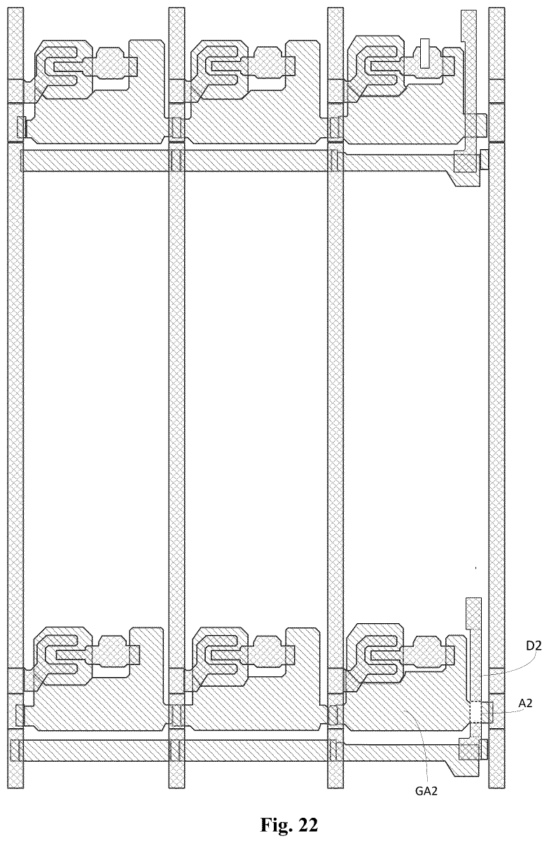

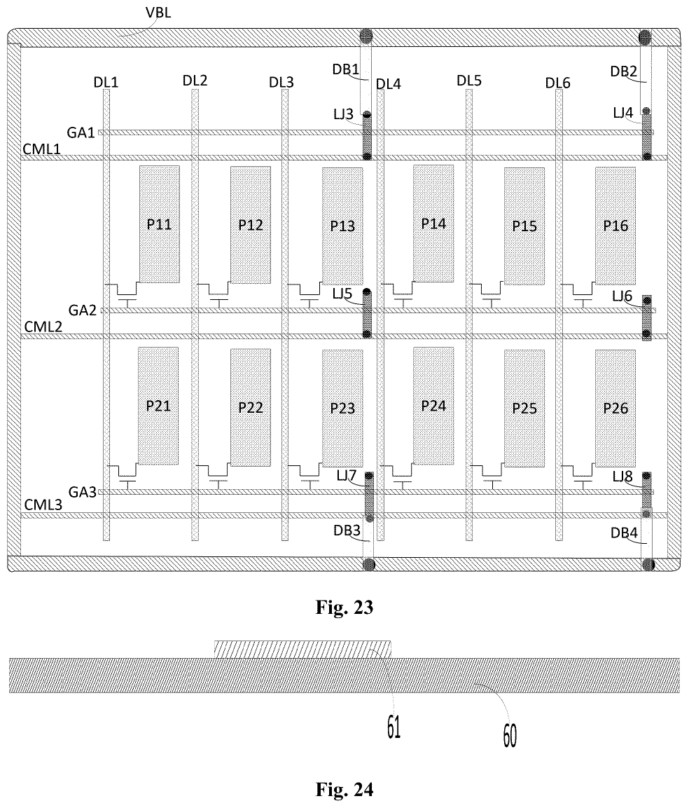

As shown in FIG. 23, the display substrate according to at least one embodiment of the present disclosure may include a first row gate line GA1, a first row common electrode line CML1, a second row gate line GA2, a second row common electrode line CML2, a third row gate line GA3, a third row common electrode line CML3, a common electrode bus VBL, a first column data line DL1, a second column data line DL2, a third column data line DL3, a fourth column data line DL4, a fifth column data line DL5, a sixth column data line DL6, a first row first column pixel electrode P11, a first row second column pixel electrode P12, and a first row third column pixel electrode P13, a first row fourth column pixel electrode P14, a first row fifth column pixel electrode P15, a first row sixth column pixel electrode P16, a second row first column pixel electrode P21, a second row second column pixel electrode P22, a second row third column pixel electrode P23, a second row fourth column pixel electrode P24, a second row fifth column pixel electrode P25, a second row sixth column pixel electrode P26 and multiple switch transistors;
GA1, GA2, GA3, CML1, CML2, CML3, and VBL are all located in the gate electrode layer;
VBL is set around the display area;
VBL, CML1, CML2, and CML3 are interconnected with each other;
DL1, DL2, DL3, DL4, DL5, and DL6 are all located in the source drain electrode layer;
P11, P12, P13, P14, P15, P16, P21, P22, P23, P24, P25, and P16 are all located in the second transparent conductive layer;
CML 1 is electrically connected to the first second-common electrode located in the first transparent conductive layer through a third connection structure LJ3, and to the second second-common electrode located in the first transparent conductive layer through a fourth connection structure LJ4; the first second-common electrode is electrically connected to VBL through a first conducting portion DB1 located in the second transparent conductive layer, and the second second-common electrode is electrically connected to VBL through a second conducting portion DB2 located in the second transparent conductive layer;
CML2 is electrically connected to the third second-common electrode located in the first transparent conductive layer through a fifth connection structure LJ5, and to the fourth second-common electrode located in the first transparent conductive layer through a sixth connection structure LJ6;
CML3 is electrically connected to a fifth second-common electrode located in the first transparent conductive layer through a seventh connection structure LJ7, and CML2 is electrically connected to a sixth second-common electrode located in the first transparent conductive layer through an eighth connection structure LJ8; CML3 is electrically connected to VBL through a third conducting portion DB3 located in the second transparent conductive layer, and CML3 is electrically connected to VBL through a fourth conducting portion DB4 located in the second transparent conductive layer.

In at least one embodiment of the present disclosure, the display substrate includes a first transparent conductive layer, a gate electrode layer, a source drain electrode layer, and a second transparent conductive layer arranged in a direction away from the base substrate in sequence;
The first conducting sub-portion in the connection structure is located in the first conductive layer; the second conducting sub-portion in the connection structure is located in the second conductive layer;
The first conductive layer is the second transparent conductive layer, and the second conductive layer is the source drain electrode layer.

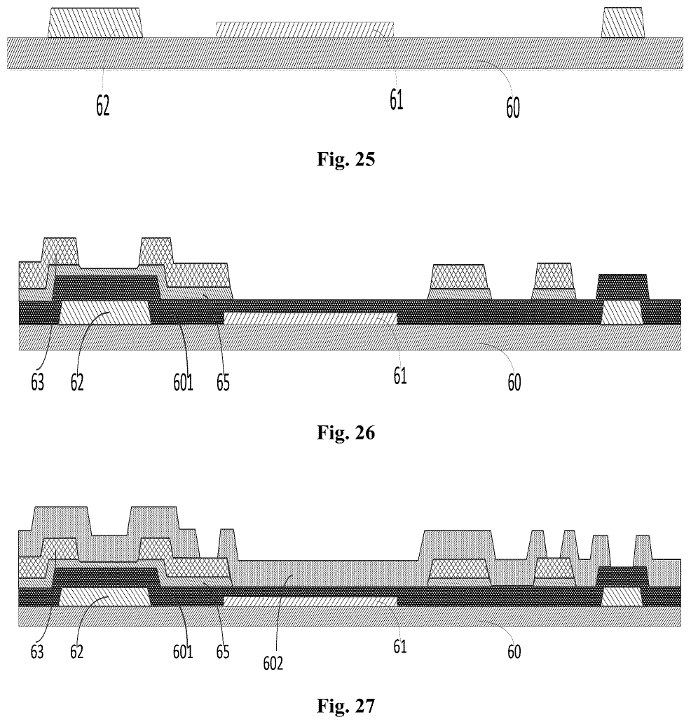

When making the display substrate, firstly, as shown in FIG. 24, a first transparent conductive layer 61 is fabricated on a base substrate 60, where the thickness of the first transparent conductive layer 61 can be 700 Angstroms. The first transparent conductive layer 61 is coated, exposed, developed, and wet etched to form a second common electrode;
As shown in FIG. 25, a gate electrode layer 62 is then fabricated, which includes a first Mo (molybdenum) layer, a first Al (aluminum) layer, and a second Mo layer sequentially arranged in a direction away from the base substrate 60, where the thickness of the first Mo layer is 150 Angstroms, the thickness of the first Al layer is 3000 Angstroms, and the thickness of the second Mo layer is 800 Angstroms. After coating, exposure, development, and wet etching, a gate line and a common electrode line are formed.

As shown in FIG. 26, after completing the production of the gate line and common electrode line, a full layer of gate insulation layer 601 is laid. The thickness of the gate insulation layer 601 is 4000 Angstroms, and the gate insulation layer 601 is made of SiNx (silicon nitride).

Next, a semiconductor layer 65 with a thickness of 1700 Angstroms is deposited, followed by a source drain electrode layer 63. The source drain electrode layer can include a third Mo (molybdenum) layer, a second Al (aluminum) layer, and a fourth Mo layer sequentially arranged in a direction away from the base substrate 60. The thickness of the third Mo layer is 150 Angstroms, the thickness of the second Al layer is 3000 Angstroms, and the thickness of the fourth Mo layer is 800 Angstroms. Then, the SSM (Single Slit Mask, single slit mask) process (4Mask(mask)process) is used, followed by one wet etching and one dry etching, forming the first electrode of the switch transistor, the second electrode of the switch transistor and channel. The first wet etching removes source drain metal, forming the first electrode of the switch transistor and the second electrode of the switch transistor. The second dry etching exposes the channel.

As shown in FIG. 27, a passivation layer 602 is then fabricated, and the entire passivation layer is deposited. The thickness of the passivation layer 602 is 4000 Angstroms. The passivation layer 602 is made of SiNx, which is exposed, developed, and etched to remove unnecessary insulation layers and expose via-holes, such as the connection via-holes, first via-hole, and second via-hole of pixel electrodes.

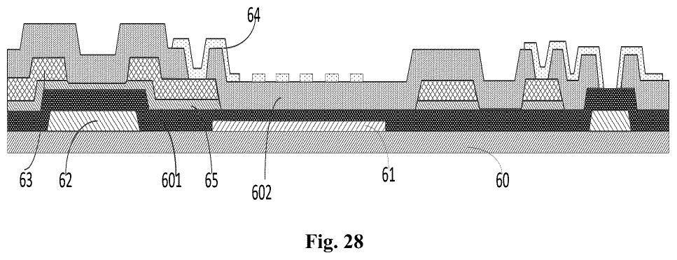

As shown in FIG. 28, a second transparent conductive layer 64 is fabricated, with a thickness of 700 Angstroms. The desired patterns (mainly pixel electrodes) and the conductive patterns located in the second transparent conductive layer included in the connection structure are formed through coating, exposure, development, and wet etching.

The process description of 4Mask is as follows: the semiconductor layer and source drain electrode layer are produced simultaneously. Compared with traditional 5Mask, 4Mask process involves depositing the semiconductor layer and source drain electrode layer together, only performing one mask after coating them with photoresist, forming partial exposure in the channel area by using SSM process, firstly etching source drain metal patterns, and then ashing exposure to produce the channel.

The display device according to the embodiments of the present disclosure includes the foregoing display substrate.

In at least one embodiment of the present disclosure, the display device may be a liquid crystal display, but not limited to this. In practical operation, the display device can also be other types of display devices.

The above are merely the preferred embodiments of the present disclosure. It should be noted that, those of ordinary skill in the art may make further improvements and modifications without departing from the principle of the present disclosure, and these improvements and modifications shall also fall within the scope of the present disclosure.

1. A display substrate, comprising: a connection structure, a first common electrode, a second common electrode, a first conductive layer, and a second conductive layer; wherein the connection structure comprises a first connection portion, a second connection portion, and a conducting portion;
the first connection portion is electrically connected to the first common electrode through a first via-hole, and the second connection portion is electrically connected to the second common electrode through a second via-hole;
the conducting portion comprises a first conducting sub-portion and a second conducting sub-portion; the first connection portion is electrically connected to the second connection portion through the first conducting sub-portion, and the first connection portion is electrically connected to the second connection portion through the second conducting sub-portion;
the first conducting sub-portion is located in the first conductive layer, and the second conducting sub-portion is located in the second conductive layer;
a length-width ratio of the first via-hole is X1, and a length-width ratio of the second via-hole is X2, with X1<1<X2;
the length-width ratio of the first via-hole is a ratio of a maximum length of the first via-hole along a first direction to a maximum width of the first via-hole along a second direction, the length-width ratio of the second via-hole is a ratio of a maximum length of the second via-hole along the first direction to a maximum width of the second via-hole along the second direction;
the first direction crosses the second direction.

2. The display substrate according to claim 1, wherein conductivity of the first conductive layer is lower than conductivity of the second conductive layer.

3. The display substrate according to claim 1, wherein the first connection portion comprises a first connection part and a second connection part; the first connection part is electrically connected to the first common electrode and the second connection part through the first via-hole;
the second connection portion comprises a third connection part and a fourth connection part, the third connection part is electrically connected to the second common electrode and the fourth connection part through the second via-hole;
the first connection part is electrically connected to the third connection part through the first conducting sub-portion, and the second connection part is electrically connected to the fourth connection part through the second conducting sub-portion.

4. The display substrate according to claim 3, further comprising a base substrate; wherein the connection structure is on the base substrate; the first via-hole comprises a first via-hole portion and a second via-hole portion arranged along the second direction;
an orthographic projection of the first via-hole portion onto the base substrate does not overlap with an orthographic projection of the second connection part onto the base substrate; the orthographic projection of the first via-hole portion onto the base substrate is within an orthographic projection of the first common electrode onto the base substrate;
an orthographic projection of the second via-hole portion onto the base substrate is within the orthographic projection of the first common electrode onto the base substrate, and the orthographic projection of the second via-hole portion onto the base substrate is within the orthographic projection of the second connection part onto the base substrate;
the orthographic projection of the second connection part onto the base substrate overlaps at least partially with the orthographic projection of the first common electrode onto the base substrate.

5. The display substrate according to claim 4, further comprising a third conductive layer;
wherein the first common electrode is located in the third conductive layer, the first connection part is located in the first conductive layer, and the second connection part is located in the second conductive layer.

6. The display substrate according to claim 3, further comprising a base substrate; wherein the connection structure is on the base substrate; the second via-hole comprises a third via-hole portion and a fourth via-hole portion arranged along the first direction;
an orthographic projection of the third via-hole portion onto the base substrate does not overlap with an orthographic projection of the fourth connection part onto the base substrate; the orthographic projection of the third via-hole portion onto the base substrate is within an orthographic projection of the third connection part onto the base substrate;
an orthographic projection of the fourth via-hole portion onto the base substrate is within the orthographic projection of the fourth connection part onto the base substrate; the orthographic projection of the fourth via-hole portion onto the base substrate is within the orthographic projection of the third connection part onto the base substrate;
the orthographic projection of the fourth connection part onto the base substrate overlaps at least partially with an orthographic projection of the second common electrode onto the base substrate.

7. The display substrate according to claim 6, further comprising a fourth conductive layer; wherein the second common electrode is located in the fourth conductive layer, the third connection part is located in the first conductive layer, and the fourth connection part is located in the second conductive layer.

8. The display substrate according to claim 1, wherein X1 is less than or equal to 0.8, and X2 is greater than or equal to 1.2;
and/or,
wherein X1/X2 is greater than or equal to 0.3 and less than or equal to 0.6.

9. (canceled)

10. The display substrate according to claim 4, wherein a distance between a first edge of the orthographic projection of the second via-hole portion onto the base substrate and a second edge of the orthographic projection of the second connection part onto the base substrate is greater than a first distance, and the first distance is greater than or equal to 1.9 μm but less than or equal to 2.3 μm;
the first edge is opposite to the second edge;
or,
wherein a shortest distance along the second direction between an edge of the orthographic projection of the first via-hole portion onto the base substrate and an edge of the orthographic projection of the second connection part onto the base substrate is greater than a second distance, and the second distance is greater than or equal to 1.9 μm but less than or equal to 2.3 μm;
or,
wherein a length of the second via-hole portion along the second direction is greater than a first length, and the first length is greater than or equal to 3.9 μm and less than or equal to 4.3 μm:
or,
wherein a distance between an edge of the orthogonal projection of the first via-hole onto the base substrate and an edge of the orthogonal projection of the first connection part onto the base substrate is greater than a third distance, and the third distance is greater than or equal to 1.9 μm but less than or equal to 2.3 μm;
or,
wherein a length of the first via-hole along the first direction is greater than a second length, and the second length is greater than or equal to 3.8 μm but less than or equal to 4.2 μm.

11. (canceled)

12. (canceled)

13. (canceled)

14. (canceled)

15. The display substrate according to claim 6, wherein a distance between a third edge of the orthogonal projection of the fourth via-hole portion onto the base substrate and a fourth edge of the orthogonal projection of the fourth connection part onto the base substrate is greater than a fourth distance, and the fourth distance is greater than or equal to 1.9 μm but less than or equal to 2.3 μm;
the third edge is opposite to the fourth edge.

16. The display substrate according to claim 6, wherein a shortest distance along the second direction between an edge of the orthographic projection of the third via-hole portion onto the base substrate and an edge of the orthographic projection of the fourth connection part onto the base substrate is greater than a fifth distance, and the fifth distance is greater than or equal to 1.9 μm but less than or equal to 2.3 μm.

17. The display substrate according to claim 6, wherein a length of the fourth via-hole portion along the first direction is greater than a third length, and the third length is greater than or equal to 3.9 μm and less than or equal to 4.3 μm.

18. The display substrate according to claim 5, wherein a shortest distance along the first direction between an edge of the orthographic projection of the second via-hole onto the base substrate and an edge of the orthographic projection of the third connection part onto the base substrate is greater than a sixth distance, and the sixth distance is greater than or equal to 1.9 μm but less than or equal to 2.3 μm.

19. The display substrate according to claim 5, wherein a length of the second via-hole along the second direction is greater than a fourth length, and the fourth length is greater than or equal to 3.8 μm but less than or equal to 4.2 μm.

20. The display substrate according to claim 4, wherein a length of the orthographic projection of the first via-hole portion onto the base substrate along the first direction is greater than a length of the orthographic projection of the second via-hole portion onto the base substrate along the first direction; or,
the length of the orthographic projection of the first via-hole portion onto the base substrate along the first direction is smaller than the length of the orthographic projection of the second via-hole portion onto the base substrate along the first direction.

21. The display substrate according to claim 6, wherein a length of the third via-hole portion along the second direction is greater than a length of the fourth via-hole portion along the second direction; or,
the length of the third via-hole portion along the second direction is smaller than the length of the fourth via-hole portion along the second direction.

22. The display substrate according to claim 1, further comprising a base substrate and a gate line on the base substrate;
wherein there is a first overlapping region between an orthographic projection of the gate line onto the base substrate and an orthographic projection of the first conducting sub-portion of the connection structure onto the base substrate;
there is a second overlapping region between the orthographic projection of the gate line onto the base substrate and an orthographic projection of the second conducting sub-portion of the connection structure onto the base substrate;
an area of the first overlapping region is smaller than an area of the second overlapping region.

23. The display substrate according to claim 1, further comprising a base substrate, and a pixel electrode, a data line, a gate line, and a switch transistor on the base substrate;
wherein the gate line comprises a first gate line portion and a second gate line portion that are interconnected with each other; the first gate line portion is reused as the gate electrode of the switch transistor;
a first electrode of the switch transistor is electrically connected to the data line;
a second electrode of the switch transistor comprises a transfer portion, a first electrode portion, and a second electrode portion; the transfer portion is electrically connected to the pixel electrode, the first electrode portion is on a first side of the transfer portion, and the second electrode portion is on a second side of the transfer portion, wherein the first side and the second side are opposite sides;
an orthographic projection of the first electrode portion onto the base substrate overlaps at least partially with an orthographic projection of the first gate line portion onto the base substrate;
an orthographic projection of the second electrode portion onto the base substrate overlaps at least partially with an orthographic projection of the second gate line portion onto the base substrate.

24. The display substrate according to claim 1, further comprising a base substrate; wherein the display substrate comprises a first transparent conductive layer, a gate electrode layer, a source drain electrode layer, and a second transparent conductive layer arranged in a direction away from the base substrate in sequence;
the first conductive layer is the second transparent conductive layer, and the second conductive layer is the source drain electrode layer.

25. A display device, comprising a display substrate;
wherein the display substrate comprises: a connection structure, a first common electrode, a second common electrode, a first conductive layer, and a second conductive laver; wherein the connection structure comprises a first connection portion, a second connection portion. and a conducting portion;
the first connection portion is electrically connected to the first common electrode through a first via-hole, and the second connection portion is electrically connected to the second common electrode through a second via-hole;
the conducting portion comprises a first conducting sub-portion and a second conducting sub-portion; the first connection portion is electrically connected to the second connection portion through the first conducting sub-portion, and the first connection portion is electrically connected to the second connection portion through the second conducting sub-portion;
the first conducting sub-portion is located in the first conductive layer, and the second conducting sub-portion is located in the second conductive laver:
a length-width ratio of the first via-hole is X1. and a length-width ratio of the second via-hole is X2, with X1<1<X2;
the length-width ratio of the first via-hole is a ratio of a maximum length of the first via-hole along a first direction to a maximum width of the first via-hole along a second direction. the length-width ratio of the second via-hole is a ratio of a maximum length of the second via-hole along the first direction to a maximum width of the second via-hole along the second direction;
the first direction crosses the second direction.
